(19) United States
(12) Patent Application Publication
(10) Pub. No.: US 2004/0193989 A1
(43) Pub. Date: Sep. 30, 2004

(54) Test system including a test circuit board including through-hole vias and blind vias

(75) Inventors: Edward Hugh Welbon, Austin, TX (US); Roy Stuart Moore, Georgetown, TX (US)

Correspondence Address: B. Noel Kivlin, Meyertons, Hood, Kivlin, Kowert & Goetzel, P.C., P.O. Box 398, Austin, TX, 78767, US

(73) Assignee: Sun Microsystems, Inc., Santa Clara, CA

(21) Appl. No.: 10/401,484

(22) Filed: Mar. 28, 2003

(51) Int. Cl. G01R 31/28; G06F 11/00

(52) U.S. Cl. 714/742

(57) ABSTRACT

A test system for testing a device under test which includes a plurality of output signal contacts arranged in a particular footprint pattern. The test system may include a test chip which may have a plurality of input signal contacts for receiving signals conveyed from the device under test. The plurality of input signal contacts may be arranged to symmetrically match the particular footprint pattern. The test chip may further include additional contacts for conveying output signals to be analyzed. In addition, the test system includes a test circuit board including a plurality of through-hole vias that connect the plurality of output signal contacts to the plurality of input signal contacts. Further, the test circuit board may include a plurality of blind vias for conveying the output signals to be analyzed to an analyzer unit.

### BACKGROUND OF THE INVENTION

1. Field of the Invention

This invention relates to test systems and, more particularly, to test circuit boards for conveying output signals of a device under test.

2. Description of the Related Art

Analyzing output signals from a device under test may be done in a variety of ways. One way is to use a test circuit board or patch board. The output signals which are to be analyzed may be routed or coupled to the test board and then further routed to an analyzer port for connection to an analyzer. In some test systems, a test circuit board may be connected directly to the device under test using cables, connectors and sockets. In other test systems, the device under test may be mounted to a standard system board and the test circuit board may be coupled to the system board using cables or connectors.

Circuit boards come in many different types. One common type of circuit board is a printed circuit board. Printed circuit boards generally have one or more layers of insulating or dielectric material which may be laminated together. Each layer may include multiple signal paths or “signal traces” which are used to propagate signals. In addition, some layers may be used only to provide power or ground and may be considered as a solid plane. These types of layers are typically referred to as power and ground planes, respectively. Further, other layers may include both power or ground planes as well as signal traces.

The signal traces are typically thin metallic “wires” which have been etched from a pattern which has been printed onto a metal layer which may be bonded to the surface of the circuit board. The metal is generally copper or some other similar conductive copper alloy. Depending on the type of process used to manufacture the circuit board, the unused metal may be etched away leaving the signal traces and any other metallic contact surfaces intact.

To connect signals, power and ground between layers, one or more types of “vias” may be used. Generally speaking a via is a hole that is drilled or bored through one or more layers of a circuit board. A metallic finish is plated to the inside surface of the hole, thereby enabling traces or connections on each layer to be connected. One type of via is a through-hole via. A through-hole via is typically a hole which is bored completely through all circuit board layers, thereby enabling any layer to connect to any other layer. Another type of via is a blind via. Blind vias are typically used to connect a surface layer such as a top or bottom layer to an inner layer. Thus, a blind via may be bored through one or more layers but not completely through all layers of a circuit board. Another type of via is a buried via. Buried vias are typically used to connect internal layers of the circuit board. A buried via may be bored through internal circuit board layers and may thus be hidden from either surface of the circuit board.

Depending on the frequency of the output signals, the loading placed on the output signals by the analyzer and by the wiring and traces of the test circuit board may be big enough to distort the outputs signals. This distortion may cause incorrect measurements and possibly even precluding normal system operation. Accordingly, when probing any signal it may be advantageous to keep the lead lengths of any probe wires as short as possible to reduce the amount of load that the probe adds to the output signal. However when the device under test is packaged in a carrier which has a high pin count and thus a high signal density, it may be difficult to route the probe wires or traces on a circuit board.

### SUMMARY OF THE INVENTION

Various embodiments of a test system are disclosed. In one embodiment, a test system includes a device under test which includes a plurality of output signal contacts arranged in a particular footprint pattern. The test system may further include a test chip which may include a plurality of input signal contacts for receiving signals conveyed from the device under test. The plurality of input signal contacts may be arranged to symmetrically match the particular footprint pattern. The test chip may further include additional contacts for conveying output signals to be analyzed. In addition, the test system includes a test circuit board including a plurality of through-hole vias that connect the plurality of output signal contacts to the plurality of input signal contacts. Further, the test circuit board may include a plurality of blind vias for conveying the output signals to be analyzed to an analyzer unit.

### BRIEF DESCRIPTION OF THE DRAWINGS

FIG. 1 is a block diagram of one embodiment of a test system.

FIG. 2 is a perspective view drawing of one embodiment of the test system of FIG. 1.

FIG. 3 is a cross-section of one embodiment of a test circuit board of the test system of FIG. 2.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

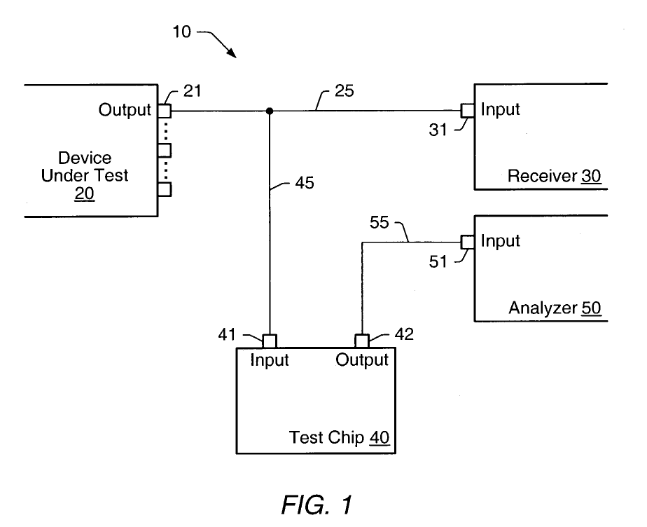

Turning now to FIG. 1, a block diagram of one embodiment of a test system is shown. Test system 10 includes a device under test (DUT) 20. DUT 20 includes an output signal contact 21 coupled to an input pin 31 of a receiver device 30 via a signal path 25. In addition, output signal contact 21 is coupled to an input signal contact 41 of test chip 40 via a signal path 45. Test chip 40 is further coupled to an input pin 51 of an analyzer unit 50.

In one embodiment, DUT 20 may be a high performance processor, for example. During operation, DUT 20 may output signals on a variety of contacts. To capture the output on analyzer 50, some preprocessing of the output signals may be necessary. In the illustrated embodiment, test chip 40 may be configured to first capture the output signals and performs some type of processing as necessary. For example, test chip 40 may coalesce the output signals from one or more output signal groups into a single output. Test chip 40 may then output the processed signals for use by analyzer 50. To effectively capture the output signals from DUT 20, a test board (not shown in FIG. 1) may be used. Test chip 40 may be mounted to the test board and outputs may be provided for connections to analyzer 50.

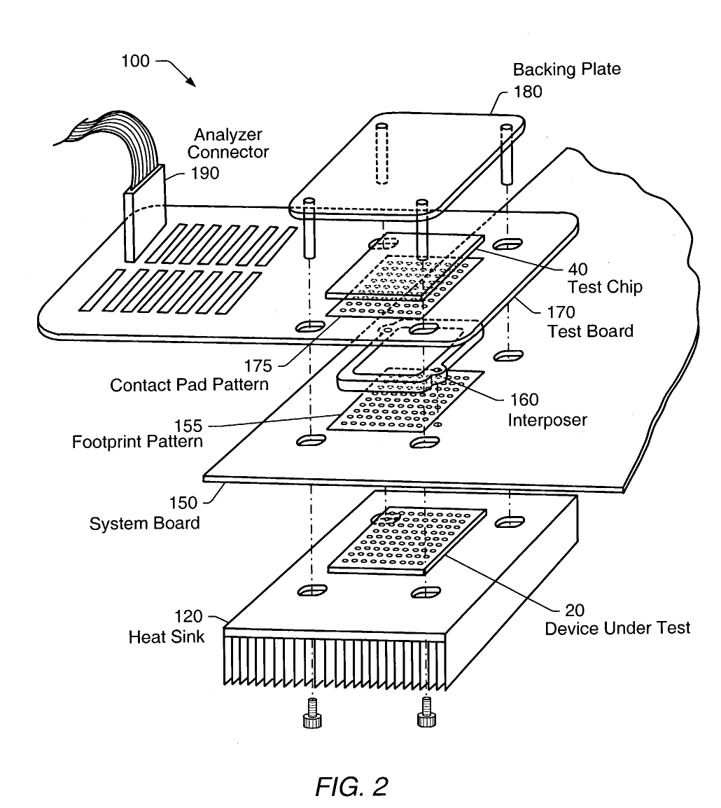

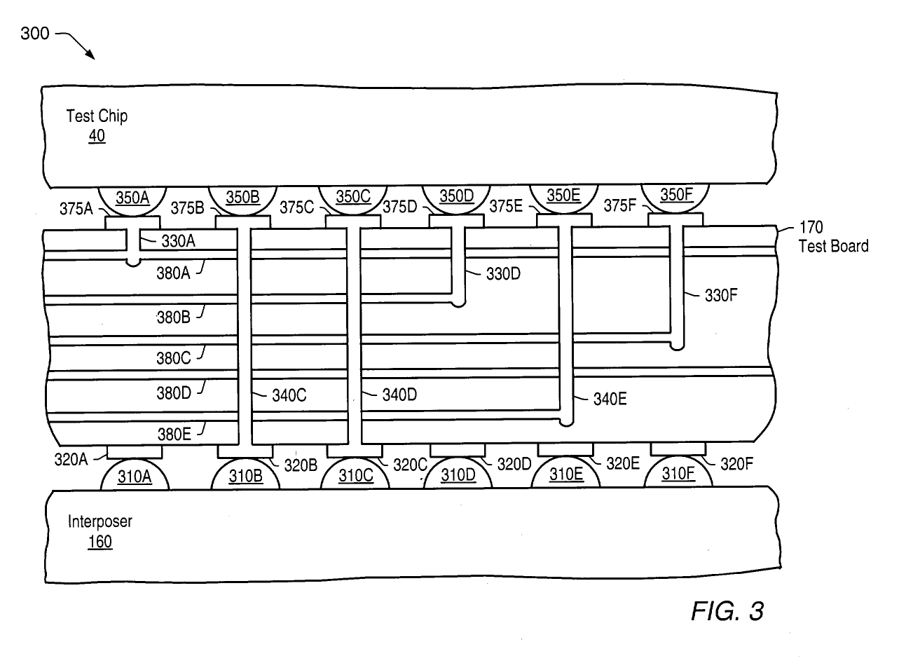

Depending on the frequency signals produced at output signal contact 21 of DUT 20, the load created by signal path 45 and test chip 40 may cause distortion of the output signal. Accordingly, lead lengths and associated test wiring should be minimized. As will be described in greater detail below in conjunction with the description of FIG. 2 and FIG. 3, test chip 40 may provide signal isolation from analyzer 50. In addition, a test circuit board using a combination of through-hole and blind vias to convey the output signals of DUT 20 may minimize loading effects of the test circuit board and test chip 40.

Referring to FIG. 2, a perspective view drawing of one embodiment of the test system of FIG. 1 is shown. Components corresponding to those shown in FIG. 1 are numbered identically for clarity and simplicity. Test system 100 includes a device under test (DUT ) 20 which may be mounted to a heat sink 120 and to a system board 150. System board 150 is coupled to a test board 170 through an interposer 160. Test system 100 also includes a test integrated circuit chip 40 which is coupled to test board 170. Test system 100 also includes a backing plate 180 which provides a mechanism to hold the various components together. Further, an analyzer connector 190 may be coupled to test board 170 via a corresponding connector on test board 170.

Backing plate 180 may be used to “sandwich” test chip 40, test board 170, interposer 160, system board 150, DUT 20 and heat sink 120 together. In the illustrated embodiment, thumb-screws or other suitable fasteners may be used to fasten backing plate 180 to heat sink 120. This arrangement may compress each contact on DUT 20, interposer 160 and test chip 40 to their respective contact pads on their respective circuit boards.

In the illustrated embodiment, DUT 20 uses a ball grid array (BGA) for its contact pinout. The BGA forms a given footprint pattern. The footprint pattern of DUT 20 is mated to a footprint pattern 155 on system board 150. Footprint pattern 155 is provided on both the top and bottom surface of system board 150. To keep lead lengths as short as possible, the footprint pattern on each board surface is symmetrically matching and also positioned opposite other. Accordingly, a footprint pattern on the bottom of interposer 160 mates to footprint pattern 155 on the top surface of system board 150. In addition, a footprint pattern on the top of interposer 160 mates to a footprint pattern on the bottom of test board 170, and so forth. It is noted that although a BGA footprint pattern is used in the illustrated embodiment, other embodiments are contemplated in which other footprint patterns may be used.

In one embodiment, system board 150 may be any circuit board which is used in the normal operation of DUT 20. For example, if DUT 20 is a processor, system board 150 may be a processor motherboard. However, in other embodiments, system board 150 may be special circuit board designed to emulate a typical system environment as seen from DUT 20.

In the illustrated embodiment, interposer 160 may provide a means for conveying signals from system board 150 to test board 170 while allowing clearance of other components on system board 150. In other words, interposer 160 may be a spacer which also conveys signals. As described above, interposer 160 may include a set of contacts on each side which have a footprint pattern which matches footprint pattern 155. In addition the contacts of interposer 160 may be flexible or spring loaded to provide a compression connection when mated between system board 150 and test board 170.

In the illustrated embodiment, test board 170 is a circuit board which provides signal paths for capturing output signals which are conveyed from DUT 20. Further, test board 170 may provide signal paths for the output signals to be conveyed from test chip 40 to an analyzer unit (not shown in FIG. 2).

As described above, an analyzer unit such as analyzer unit 50 of FIG. 1 may be configured to capture the transactions which occur at the interface of DUT 20. It may be important that these transactions be collected contiguously and at system speeds. It may be additionally important that the acquired transactions be time-stamped. Further, it may be important for the acquired transactions to be efficiently packed in analyzer records. However, in many advanced bus structures, the buses may be broken up into smaller pieces or multiplexed such that the signal groups pertinent to a given transaction may not be output during a single clock cycle. For many analyzers, it may be difficult or impossible to coalesce the signals pertinent to the given transaction and/or to efficiently store the data.

In the illustrated embodiment, a test chip 40 may be configured to capture output signals from DUT 20 and to perform pre-processing on the signals. The pre-processing may simplify the analysis of the output signals from DUT 20. For example, test chip 40 may coalesce multiple groups of signals which may be captured at different time intervals into single capture cycles including packed groups of signals. Test chip 40 may then output the coalesced signals for analysis by an analyzer unit (not shown in FIG. 2). In other embodiments, test chip 40 may simply repeat the captured signals. For example, test chip 40 may capture the output signals from DUT 20 and then output the captured signals for analysis by the analyzer unit, thereby isolating the output signals from DUT 20 for the analyzer.

As described above, test chip 40 uses a footprint pattern which mirrors footprint pattern 155. Acquiring the output signals of DUT 20 may be straightforward and may be accomplished using through-hole vias from the bottom of test board 170 to the top test board 170. However, routing the coalesced output signals from test chip 40 to analyzer connector 190 may be problematic on a conventional circuit board. As will be described in greater detail below in conjunction with the description of FIG. 3, the output signals from test chip 40 may be routed to analyzer connector 190 using blind vias on test board 170.

Turning to FIG. 3, a cross-section of one embodiment of the test board of the test system of FIG. 2 is shown. Components corresponding to those shown in FIG. 1 and FIG. 2 are numbered identically for clarity and simplicity. Test board 170 includes a plurality of contact pads on the top surface. The top surface contact pads are designated 375A through 375E. Test board 170 also includes a plurality of contact pads on the bottom surface. The bottom surface contact pads are designated 320A through 320E. The top and bottom contact pads are arranged to form footprint patterns as described above in conjunction with the description of FIG. 2. In addition test board 170 includes a plurality of layers which include a plurality of signal planes designated 380A through 380E. As described above, layers of a circuit board may be interconnected using different types of vias. Thus, test board 170 includes both through-hole vias 340B and 340C and blind vias 330A, and 330D through 330F. It is noted that only a portion of test board 170 is shown and that only five top and bottom surface contact pads are shown for simplicity. It is contemplated that other embodiments include any suitable number of contact pads.

Contact pads 320A-F are shown mated to contacts on interposer 160. As described above, interposer 160 may provide a feed through for signals originating on system board 150 and more particularly, DUT 20.

Contact pads 375A-F are shown mated to contacts 350-350F, respectively on test chip 40. As described above, test chip 40 may receive and capture signals output from DUT 20. Test chip 40 may perform pre-processing of the signals and then output the processed signals for use by an analyzer unit such as analyzer unit 50 of FIG. 1.

To minimize the loading effects of test chip 40 and its associated wiring on the output signals of DUT 20, a special routing of the test chip 40 input and output signals is provided on test board 170. As shown in FIG. 3, contact 310B of interposer 160 is mated to contact pad 320B of test board 170. Contact pad 320B is connected to contact pad 375B using a through-hole via 340B. It is noted that through-hole via 340B may provide an essentially straight-line connection between contact pads 320B and 375B. This arrangement may minimize any distortion of the output signals of DUT 20 that are to be analyzed. Contact pad 375B is mated to contact 350B of test chip 40. This signal path is representative of a DUT 20 output signal being routed to an input contact of test chip 40. A similar path is shown from contact 320C of interposer 160. Thus, contacts on DUT 20 which correspond to contacts 310B and 310C of interposer 160 convey output signals of DUT 20 which need to be analyzed.

However, contacts on DUT 20 which correspond to contacts 310A and 310D-310F may be signals which are not to be analyzed. Accordingly, contact pads 375A and 375D-375F, which correspond to those locations, need not connect to the bottom contact pads using through-hole vias. Instead, the space made available by the absence of through-hole vias may be used by contact pads 375A and 375D-375F to convey test chip 40 output signals to analyzer connector 190 using blind vias 330A and 330D-330F. Similarly, other contact pads on test board 170 which do not correspond to DUT 20 output signals which need to be captured may be used to convey test chip 40 output signals using blind vias.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A test system comprising:
a device under test including a plurality of output signal contacts arranged in a particular footprint pattern;
a test chip including a plurality of input signal contacts for receiving signals conveyed from said device under test, wherein said plurality of input signal contacts are arranged to symmetrically match said particular footprint pattern;
wherein said test chip further includes additional contacts for conveying output signals to be analyzed; and
a test circuit board including a plurality of through-hole vias that connect said plurality of output signal contacts to said plurality of input signal contacts, wherein said test circuit board further includes a plurality of blind vias for conveying said output signals to be analyzed to an analyzer unit.

2. The test system as recited in claim 1, wherein said device under test includes additional contacts for conveying additional signals which are not analyzed.

3. The test system as recited in claim 2, wherein said additional contacts of said device under test are symmetrically arranged to match said additional contacts of said test chip.

4. The test system as recited in claim 1, wherein said test circuit board further includes a plurality of contact pads, wherein a respective one of a first portion of said contact pads is connected to a respective one of said plurality of through-hole vias.

5. The test system as recited in claim 4, wherein a respective one of a second portion of said contact pads is connected to a respective one of said plurality of blind vias.

6. The test system as recited in claim 1, wherein said output signals to be analyzed include said signals conveyed from said device under test which have been captured and processed by said test chip.

7. The test system as recited in claim 1 further comprising a system board coupled to said device under test and configured to operate said device under test in an operational mode.

8. The test system as recited in claim 7, wherein said system board includes a device footprint pattern which matches said particular footprint pattern.

9. The test system as recited in claim 7 further comprising an interposer coupled between said system board and said test circuit board and configured to propagate said signals conveyed from said device under test to said test circuit board.

10. The test system as recited in claim 9, wherein said interposer includes a contact pad footprint pattern which matches said particular footprint pattern.

11. A method of testing a device including a plurality of output signal contacts arranged in a particular footprint pattern, said method comprising:
providing a test chip including a plurality of input signal contacts for receiving signals conveyed from said device, wherein said plurality of input signal contacts are arranged to symmetrically match said particular footprint pattern;
wherein said test chip further includes additional contacts for conveying output signals to be analyzed; and
providing a test circuit board including a plurality of through-hole vias that connect said plurality of output signal contacts to said plurality of input signal contacts, wherein said test circuit board further includes a plurality of blind vias for conveying said output signals to be analyzed to an analyzer unit.

12. The method as recited in claim 11 further comprising conveying additional signals through additional contacts of said device which are not analyzed.

13. The method as recited in claim 12, wherein said additional contacts of said device are symmetrically arranged to match said additional contacts of said test chip.

14. The method as recited in claim 11, wherein said test circuit board further includes a plurality of contact pads, wherein a respective one of a first portion of said contact pads is connected to a respective one of said plurality of through-hole vias.

15. The method as recited in claim 14, wherein a respective one of a second portion of said contact pads is connected to a respective one of said plurality of blind vias.

16. The method as recited in claim 11, wherein said output signals to be analyzed include said signals conveyed from said device which have been captured and processed by said test chip.

17. The method as recited in claim 11 further comprising providing a system board coupled to said device for operating said device in an operational mode.

18. The method as recited in claim 17, wherein said system board includes a device footprint pattern which matches said particular footprint pattern.

19. The method as recited in claim 17 further comprising providing an interposer coupled between said system board and said test circuit board for propagating said signals conveyed from said device to said test circuit board.

20. The method as recited in claim 19, wherein said interposer includes a contact pad footprint pattern which matches said particular footprint pattern.
